(19) United States
(12) Patent Application Publication
(10) Pub. No.: US 2025/0293018 A1
(43) Pub. Date: Sep. 18, 2025

(54) SEMICONDUCTOR DEVICE AND METHOD FOR MANUFACTURING THE SAME

(71) Applicant: TOYODA GOSEI CO., LTD., Kiyosu-shi (JP)

(72) Inventor: Takatomi IZUMI, Kiyosu-shi (JP)

(21) Appl. No.: 19/059,780

(22) Filed: Feb. 21, 2025

(30) Foreign Application Priority Data
Mar. 15, 2024 (JP) 2024-041551

(51) Int. Cl. H01L 21/02; H10D 62/85

(52) U.S. Cl. CPC H01L 21/02252; H01L 21/02255; H01L 21/02458; H01L 21/0254; H10D 62/8503

(57) ABSTRACT

A semiconductor device using a group III nitride semiconductor and a method for manufacturing the semiconductor device. The method includes a first oxide film forming step of forming a first oxide film with an insulation property on or above a semiconductor layer made of a group III nitride semiconductor, a nitrogen plasma treatment step of irradiating the first oxide film with nitrogen plasma, thereby injecting nitrogen into the first oxide film, a first heat treatment step of performing first heat treatment on the first oxide film to nitride the first oxide film, thereby forming an oxynitride film, a second oxide film forming step of forming a second oxide film with an insulation property on or above the oxynitride film, and a second heat treatment step of performing second heat treatment on the second oxide film. In the nitrogen plasma treatment step, a microwave output is set to 300 W or less.

### BACKGROUND OF THE INVENTION

### CROSS-REFERENCE

This application claims priority to Japanese Patent Application No. 2024-041551 filed on Mar. 15, 2024, the contents of which are fully incorporated herein by reference.

### TECHNICAL FIELD

The present disclosure relates to a semiconductor device and a method for manufacturing the semiconductor device.

### BACKGROUND ART

Group III nitride semiconductors, represented by GaN, have a high dielectric breakdown field strength. Therefore, group III nitride semiconductors are expected to be used as materials for power devices, and semiconductor devices using group III nitride semiconductors have been actively researched and developed.

JP-A-2022-14832 discloses a MISFET using GaN, in which a gate insulating film is formed in the following manner. First, a first oxide film made of SiO₂ is formed on a semiconductor layer made of GaN. Next, the first oxide film is irradiated with nitrogen plasma. The first oxide film is nitridated to thereby form laminated layers of SiON and SiN in this order from the semiconductor layer side. Then, a first heat treatment is performed. And then, a second oxide film made of SiO₂ is formed on SiN, and a second heat treatment is performed. It is thought that the oxidation of Ga on the GaN surface can be curtailed in this way.

### SUMMARY OF THE INVENTION

When the GaN surface is exposed to an atmosphere, the GaN outermost surface reacts with oxygen, thus forming a Ga—O bond. This Ga—O bond causes current leakage. In particular, when defects are formed due to removal of nitrogen from GaN by etching during forming a trench, Ga—O bonds are easily formed. Also, when an insulating film is formed on GaN using oxygen gas, as in the ALD (Atomic Layer Deposition Method), Ga—O bonds are easily formed on the GaN surface. However, it has been difficult to remove such Ga—O bonds formed on the GaN surface.

JP-A-2022-14832 discloses that near the GaN surface under an insulating film, oxidation of Ga can be curtailed. However, the microwave output during nitriding treatment by irradiating nitrogen plasma was high, and there was a possibility of damaging semiconductors.

The present disclosure has been made in view of this background, and seeks to provide a semiconductor device and a method for manufacturing the semiconductor device, in which damage to the semiconductor is curtailed and current leakage is reduced.

One aspect of this disclosure is a method for manufacturing a semiconductor device, the method comprising:
a first oxide film forming step of forming a first oxide film with an insulation property on or above a semiconductor layer made of a group III nitride semiconductor;
a nitrogen plasma treatment step of irradiating the first oxide film with nitrogen plasma, thereby injecting nitrogen into the first oxide film;
a first heat treatment step of performing first heat treatment on the first oxide film to nitride the first oxide film, thereby forming an oxynitride film;
a second oxide film forming step of forming a second oxide film with an insulation property on or above the oxynitride film; and
a second heat treatment step of performing second heat treatment on the second oxide film, wherein
in the nitrogen plasma treatment step, a microwave output is set to 300 W or less.

Another aspect of this disclosure is a method for manufacturing a semiconductor device, the method comprising:
a first oxide film forming step of forming a first oxide film with an insulation property on or above a semiconductor layer made of a group III nitride semiconductor;
a nitrogen plasma treatment step of irradiating the first oxide film with nitrogen plasma, thereby injecting nitrogen into the first oxide film;
a first heat treatment of performing first heat treatment on the first oxide film to nitride the first oxide film, thereby forming an oxynitride film;
a second oxide film forming step of forming a second oxide film with an insulation property on or above the oxynitride film; and
a second heat treatment step of performing second heat treatment on the second oxide film, wherein
an interface between the semiconductor layer and the oxynitride film is nitrided by performing the first heat treatment to reduce a concentration of Ga—O bonded oxygen at the interface to 0.8 to 1.2 at %.

Another aspect of this disclosure is a semiconductor device comprising:
a semiconductor layer made of a group III nitride semiconductor;
a gate insulating film formed on the semiconductor layer; and
a gate electrode formed on the gate insulating film, wherein
the gate insulating film including:
   an SiON film formed on the semiconductor layer, and
   an SiO2 film formed on the SiON film in contact therewith, and
a concentration of Ga—O bonded oxygen at an interface between the semiconductor layer and the SiON film is 0.8 to 1.2 at %.

In the nitrogen plasma treatment step, the microwave output is 300 W or less. Thus, plasma damage to the semiconductor layer can be curtailed. Furthermore, the Ga—O bonds formed on the surface of the semiconductor layer can be reduced, and as a result, current leakage can be curtailed.

According to the above aspect, it is possible to provide a semiconductor device and a method for manufacturing the semiconductor device, in which damage to the semiconductor is curtailed and current leakage is suppressed.

### BRIEF DESCRIPTION OF THE DRAWINGS

FIG. 1 is a cross-sectional view that shows a configuration of a semiconductor device in an embodiment and is perpendicular to a main surface of a substrate.

FIG. 2 is an enlarged cross-sectional view showing a region of an interface between a second semiconductor layer and a gate insulating film.

FIG. 3(a), FIG. 3(b), and FIG. 3(c) are illustrations showing manufacturing steps of the semiconductor device in the embodiment.

FIG. 4(a), FIG. 4(b), and FIG. 4(c) are illustrations showing forming steps of a gate insulating film.

FIG. 5 is a flowchart showing a forming step of a gate insulating film.

FIG. 6 is a graph showing Id-Vd characteristics of a semiconductor device when gate voltage is off in Comparative Example 1.

FIG. 7 is a graph showing Id-Vd characteristics of a semiconductor device when gate voltage is off in Embodiment 1.

FIG. 8 is a graph showing the distribution of nitrogen concentration and oxygen concentration in the thickness direction.

FIG. 9 is a graph showing the distribution of Gallium concentration and oxygen concentration in the direction of thickness.

FIG. 10 is a graph showing C-V characteristics when microwave output is 200 W.

FIG. 11 is a graph showing C-V characteristics when microwave output is 500 W.

### DETAILED DESCRIPTION OF PREFERRED EMBODIMENTS

A method for manufacturing a semiconductor device comprises a first oxide film forming step of forming a first oxide film with an insulation property on or above a semiconductor layer made of a group III nitride semiconductor, a nitrogen plasma treatment step of irradiating the first oxide film with nitrogen plasma, thereby injecting nitrogen into the first oxide film, a first heat treatment step of performing first heat treatment on the first oxide film to nitride the first oxide film, thereby forming an oxynitride film, a second oxide film forming step of forming a second oxide film with an insulation property on or above the oxynitride film, and a second heat treatment step of performing second heat treatment on the second oxide film. In the nitrogen plasma treatment step, a microwave output is set to 300 W or less.

Another method for manufacturing a semiconductor device comprises a first oxide film forming step of forming an insulating first oxide film on a semiconductor layer made of a group III nitride semiconductor; a nitrogen plasma treatment step of irradiating the first oxide film with nitrogen plasma, thereby injecting nitrogen into the first oxide film, a first heat treatment step of performing first heat treatment on the first oxide film to nitride the first oxide film, thereby forming an oxynitride film, a second oxide film forming step of forming a second oxide film with an insulation property on or above the oxynitride film, and a second heat treatment step of performing second heat treatment on the second oxide film. An interface between the semiconductor layer and the oxynitride film is nitrided by performing the first heat treatment to reduce a concentration of Ga—O bonded oxygen at the interface to 0.8 to 1.2 at %.

In the method for manufacturing a semiconductor device, the interface between the semiconductor layer and the oxynitride film may be nitrided to reduce the concentration of Ga—O bonded oxygen at the interface to a level lower than before the first heat treatment step, by the first heat treatment step. Ga—O bond can be sufficiently reduced and current leakage can be more curtailed.

In the method for manufacturing a semiconductor device, in the first heat treatment step, the concentration of Ga—O bonded oxygen at the interface between the semiconductor layer and the oxynitride film may be reduced to 0.8 to 1.2 at %. The Ga—O bond can be sufficiently reduced and current leakage can be more curtailed.

In the method for manufacturing a semiconductor device, in the nitrogen plasma treatment step, the nitrogen concentration of the first oxide film may be made to be 1×10²⁰ to 1×10²²/ cm³. The concentration is sufficient to reduce the Ga—O bond.

In the method for manufacturing a semiconductor device, in the nitrogen plasma treatment step, the nitrogen concentration in the first oxide film and in a region near an interface between the semiconductor layer and the first oxide film may be made to be 1×10²¹ to 1×10²²/ cm³. The concentration is sufficient to reduce the Ga—O bond.

In the method for manufacturing a semiconductor device, in the first oxide film forming step, the first oxide film may be formed to have a thickness of 1 nm or more and 9 nm or less. This thickness makes it possible to sufficiently inject nitrogen and curtail plasma damage to the semiconductor layer.

The semiconductor device has a semiconductor layer made of a group III nitride semiconductor, a gate insulating film formed on a semiconductor layer, and a gate electrode formed on a gate insulating film. The gate insulating film includes a SiON film formed on the semiconductor layer or above and an SiO₂ film formed on the SiON film in contact therewith, and the concentration of Ga—O bonded oxygen at the interface between the semiconductor layer and the SiON film is 0.8 to 1.2 at %.

### Embodiment

### 1. Configuration of a Semiconductor Device

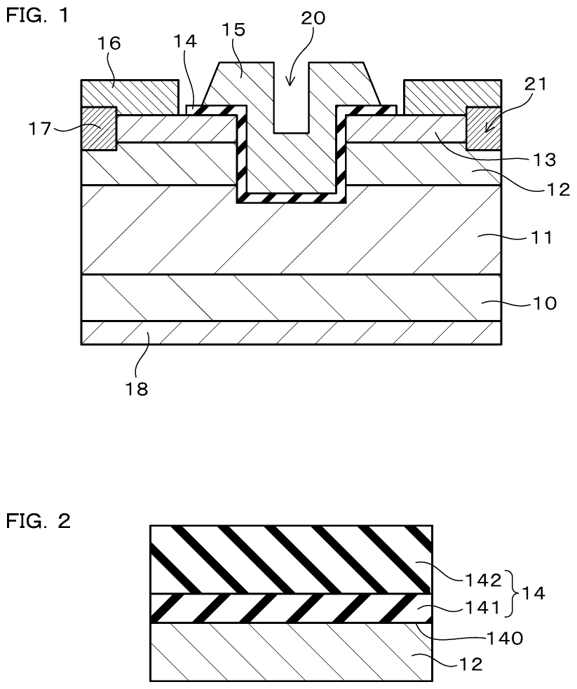

FIG. 1 is a cross-sectional view that shows of a configuration of a semiconductor device in an embodiment and is perpendicular to a main surface of a substrate. As shown in FIG. 1, the semiconductor device in the embodiment includes a substrate 10, a first semiconductor layer 11, a second semiconductor layer 12, a third semiconductor layer 13, a gate insulating film 14, a gate electrode 15, a source electrode 16, a body electrode 17, and a drain electrode 18.

The substrate 10 is made of Si-doped n⁺-GaN with the c-plane as a main surface of the substrate. The Si concentration of the substrate 10 is 1×10¹⁸/ cm³ or more.

The first semiconductor layer 11 is formed on or above the substrate 10 and is made of Si doped n⁻-GaN. The first semiconductor layer 11 functions as a drift layer. The thickness of the first semiconductor layer 11 is 8 to 15 μm. The Si concentration of the first semiconductor layer 11 is 1×10¹⁵ to 2×10¹⁶/ cm³.

The second semiconductor layer 12 is formed on or above the first semiconductor layer 11 and is made of Mg-doped p-GaN. The second semiconductor layer 12 functions as a channel layer. The thickness of the second semiconductor layer 12 is 0.1 to 1 μm. The Mg concentration of the second semiconductor layer 12 is 1×10¹⁷ to 8×10¹⁹/ cm³.

The third semiconductor layer 13 is formed on or above the second semiconductor layer 12 and is made of Si doped n⁺-GaN. The third semiconductor layer functions as a source contact layer. The thickness of the third semiconductor layer 13 is 0.1 to 0.5 μm. The Si concentration of the third semiconductor layer 13 is 1×10¹⁸ to 1×10¹⁹/ cm³.

A trench 20 is provided in a partial region of the surface of the third semiconductor layer 13. The trench 20 is a recess having a depth penetrating through the third semiconductor layer 13 and the second semiconductor layer 12 to reach the first semiconductor layer 11. The first semiconductor layer 11 is exposed to the bottom of the trench 20. The first semiconductor layer 11, second semiconductor layer 12, and third semiconductor layer 13 are exposed to the sides of trench 20 in this order from the bottom surface. The second semiconductor layer 12 exposed to the side of the trench 20 functions as a channel.

A recess 21 is provided in a partial region of the third semiconductor layer 13 where the trench 20 is not formed. The recess 21 is a concave portion having a depth penetrating through the third semiconductor layer 13 to reach the second semiconductor layer 12.

The gate insulating film 14 is continuously provided in film over the bottom, side, and top surfaces of the trench 20. The top surface of the trench 20 refers to the area near the trench 20 on the surface of the third semiconductor layer 13.

As for the gate insulating film 14, further details of the structure is explained with reference to FIG. 2. FIG. 2 is an enlarged cross-sectional view showing a region of the gate insulating film 14 which is in contact with the second semiconductor layer 12. It is noted that the gate insulating film 14 has a similar structure also in the regions other than the abovementioned region which is in contact with the second semiconductor layer 12.

As shown in FIG. 2, the gate insulating film 14 includes an oxynitride film 141 made of SiON on the second semiconductor layer 12 in contact therewith and an oxide film 142 made of SiO₂ formed on the nitride film 141. The oxide film 142 corresponds to the second oxide film in the present disclosure.

At an interface 140 between the second semiconductor layer 12 (or the first semiconductor layer 11 or the third semiconductor layer 13) and the oxynitride film 141, Ga—O bond exists. This Ga—O bond is naturally formed on the surface of gallium nitride. In other words, when gallium nitride is exposed to an atmosphere, thus oxygen reacts with the gallium nitride outermost surface, the Ga—O bond is formed. Etching damage is formed on the sides and bottom of trench 20. Therefore, when nitrogen leaves gallium nitride and thereby creates defects, Ga—O bonds are more likely to form.

This Ga—O bond leads to current leakage. Therefore, in the embodiment, the Ga—O bond is reduced by nitriding the interface 140 to thereby reducing current leakage. The nitriding method of the interface 140 is explained below in a method for forming the gate insulating film 14.

At the interface 140, the concentration of Ga—O bonded oxygen is 0.8 to 1.2 at %. In addition, the nitrogen concentration at the interface 140 is 1×10²¹ to 5×10²¹/ cm³.

The oxynitride film 141 is made of SiON and is provided on the second semiconductor layer 12 in contact therewith. The oxynitride film 141 is formed by nitriding an oxide film made of SiO₂ by performing nitrogen plasma treatment and heat treatment, as described below. The oxynitride film 141 is thin and is heat-treated at a high temperature, therefore it is difficult for oxygen atoms to migrate. Therefore, the oxynitride film 141 functions as a layer that curtails diffusion of oxygen atoms into the second semiconductor layer 12. The oxynitride film 141 also curtails injection of electron from the second semiconductor layer 12 to the gate insulating film 14.

The thickness of the oxynitride film 141 is, for example, 1 to 9 nm. By setting such a thick range, the above-mentioned effects of curtailing oxygen diffusion and curtailing electron injection can be sufficiently achieved. The thickness of the oxynitride film 141 is preferably 1 to 6 nm, and even more preferably 1 to 4 nm.

The nitrogen concentration of the oxynitride film 141 is approximately constant in a thick direction, for example, in the range of 1×10²¹ to 1×10²²/ cm³.

The oxygen concentration of the oxynitride film 141 has a distribution in the thickness direction. The oxygen concentration increases as it gets closer to the oxide film 142.

The oxide film 142 is made of SiO₂ and is provided on the oxynitride film 141 in

contact therewith. The thickness of the oxide film 142 is, for example, 40 to 100 nm. The oxide film 142 makes the gate insulating film 14 sufficiently thick.

The gate electrode 15 is provided over the bottom, the side, and the top of the trench 20 through the gate insulating film 14. The gate electrode 15 is made of, for example, TiN.

The body electrode 17 is provided on the bottom of the recess 21. The body electrode 17 is made of, for example, Ni.

The source electrode 16 is provided on or above the third semiconductor layer 13 and the body electrode 17. The source electrode 16, for example, has a multilayer film structure consisting of Pd, Al, and Ti laminated in this order from the third semiconductor layer 13 side or the body electrode 17 side.

The drain electrode 18 is provided on the back surface of substrate 10. The drain electrode 18 is made of, for example, Pd/Al/Ti.

In the semiconductor device of the embodiment, the Ga—O bond at the interface 140 between the first semiconductor layer 11, the second semiconductor layer 12, and the third semiconductor layer 13 that are under the gate insulating film 14 and the oxynitride film 141 can be reduced. As a result, the current leakage can be curtailed.

### 2. Method for Manufacturing a Semiconductor Device

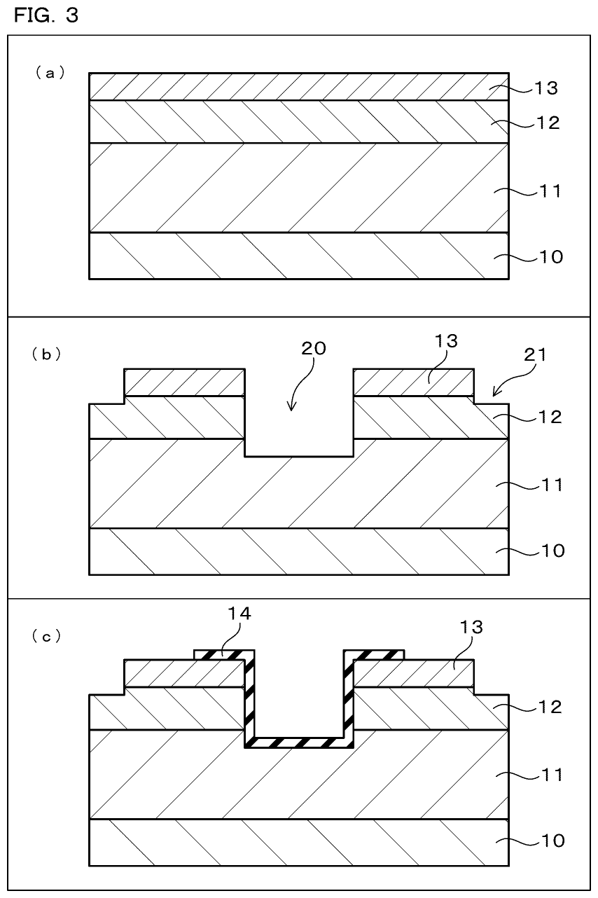

Next, the method for manufacturing a semiconductor device in an embodiment will be explained with reference to FIG. 3(a), FIG. 3(b), and FIG. 3(c).

First, on the substrate 10, the first semiconductor layer 11, the second semiconductor layer 12, and the third semiconductor layer 13 are formed in this order from the substrate 10 side (see FIG. 3(a)). As the method for forming the first semiconductor layer 11, the second semiconductor layer 12, and the third semiconductor layer 13, MOCVD is used, for example.

Next, the trench 20 is formed by performing dry etching on a predetermined region of the surface of the third semiconductor layer 13 until it reaches the first semiconductor layer 11. Then, the recess 21 is formed by performing dry etching on a predetermined region of the surface of the third semiconductor layer 13 until it reaches the second semiconductor layer 12 (see FIG. 3(b)). Wet etching may be added after the trench 20 and the recess 21 have been formed by dry etching.

Next, the gate insulating film 14 is continuously formed like a film over the bottom, the side, and the top surfaces of trench 20 (see FIG. 3(c)). The forming method of the gate insulating film 14 is described below.

Next, the gate electrode 15 is formed on the bottom, side, and top surfaces of trench 20 through the gate insulating film 14. Next, the body electrode 17 is formed on the bottom surface of the recess 21, and the source electrode 16 is formed on the third semiconductor layer 13 and the body electrode 17. Next, the drain electrode 18 is formed on the back surface of the substrate 10. These electrodes are formed, for example, by vapor deposition or sputtering. In this way, a semiconductor device of the embodiment shown in FIG. 1 is produced.

### 3. Method for Forming a Gate Insulating Film

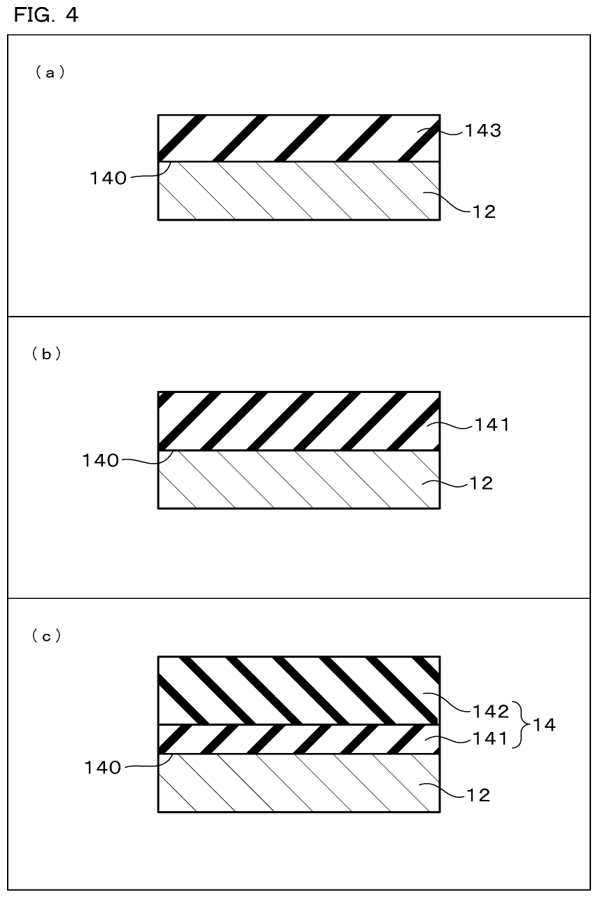

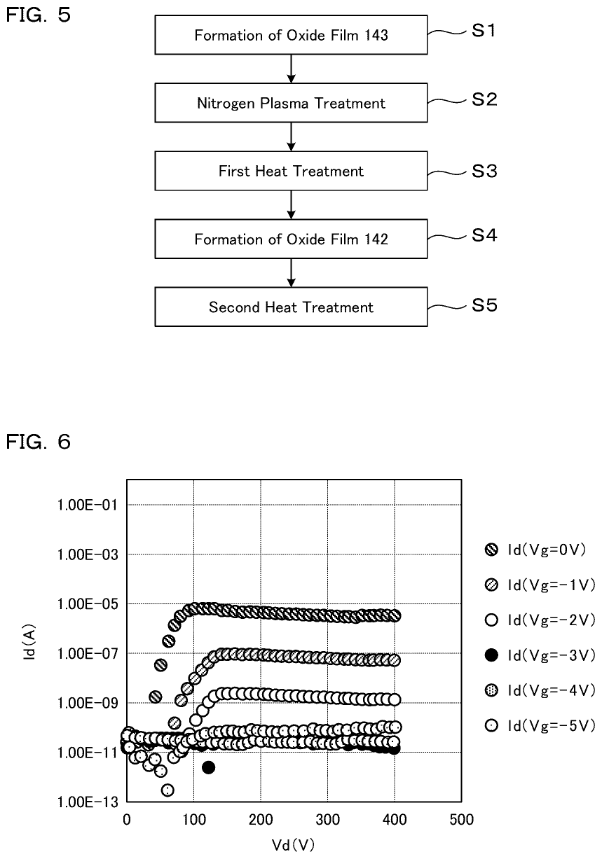

The forming method of the gate insulating film 14 is explained with reference to FIG. 4(a), FIG. 4(b), FIG. 4(c), and FIG. 5. In FIG. 4(a), FIG. 4(b), and FIG. 4(c), the area near the surface of the second semiconductor layer 12 is enlarged and shown.

First, an oxide film 143 made of SiO₂ is formed on the bottom, side, and top surfaces of the trench 20 (see FIGS. 4(a) and S1 in FIG. 5). As a forming method of the oxide film 143, CVD, ALD, or sputtering is used. The thickness of the oxide film 143 is 1 to 9 nm. Such thickness makes it possible to sufficiently inject nitrogen in the nitrogen plasma treatment in the next step and to curtail plasma damage to the semiconductor layer. The thickness of the oxide film 143 is preferably 1 to 6 nm, and even more preferably 1 to 4 nm.

Here, after forming the trench 20, the wafer is exposed to an atmosphere. The oxygen in an atmosphere reacts with the surface of GaN, especially with the nitrogen vacancies formed during forming the trench 20. Therefore, after the trench 20 has been formed, Ga—O bond is naturally formed on the GaN surface (the interface 140 between GaN and the oxide film 143). Also, in the case of using an oxygen gas in the forming method of the oxide film 143, Ga—O bond is easily formed at the interface 140, similarly.

Next, the nitrogen plasma treatment is performed by irradiating nitrogen plasma on the surface of the oxide film 143 (S2 in FIG. 5). Nitrogen gas is used as the plasma gas. The plasma source is only required to be able to generate high-density plasma, and ECR plasma, ICP, CCP, SWP, etc. can be used. By this nitrogen plasma treatment, nitrogen is injected into the oxide film 143 and the interface 140. Because the oxide film 143 is sufficiently thin, nitrogen reaches the interface 140.

By injecting nitrogen in the nitrogen plasma treatment, a nitrogen concentration (an average in the thickness direction) of the oxide film 143 falls within the range of, for example, 1×10²⁰ to 1×10²²/ cm³.

The time for the nitrogen plasma treatment is, for example, 10 to 50 minutes. The temperature of the substrate is, for example, 0 to 300° C., and the biasing electric power to the substrate side is 0 W.

When irradiating with nitrogen plasma, charged particles such as electrons and ions are preferably removed so as to irradiate only radicals. To remove the charged particles, a method using a wire mesh, a method applying a magnetic field, etc. is available. By sufficiently distancing the substrate from the plasma generation region and weakening the bias to the substrate, the charged particles may be difficult to reach the substrate.

When generating nitrogen plasma, microwave output is set to be 300 W or less. By sufficiently suppressing the microwave output, it is possible to curtail damage to the GaN to be caused by nitrogen reaching the first semiconductor layer 11, the second semiconductor layer 12, and the third semiconductor layer. However, if the microwave output is too weak, nitrogen will not be sufficiently injected to the interface 140, therefore the microwave output is preferably 50 W or more. Microwave output is more preferably 100 to 300 W, and even more preferably 100 to 200 W.

Next, heat treatment is performed in an inert gas atmosphere (S3 in FIG. 5). This heat treatment is hereinafter referred to as a first heat treatment. The inert gas is nitrogen. The temperature in the first heat treatment is, for example, 800 to 1000° C., and the time of the first heat treatment is 10 to 60 minutes.

This first heat treatment causes defects in the oxide film 143 and the interface 140 to bond with nitrogen and to be nitrided. As a result, the oxide film 143 changes from SiO₂ to SiON and forms the oxynitride film 141. The interface 140 is also nitridated, thus reducing the G—O bond existing at the interface 140. For example, the concentration of Ga—O bonded oxygen at the interface 140 is reduced from approximately 2 to 3 at % to 0.8 to 1.2 at %. Thus, because the concentration of Ga—O bonded oxygen at the interface 140 is reduced by the first heat treatment, current leakage through the interface 140 can be reduced.

In addition, the first heat treatment makes the nitrogen concentration in the oxynitride film 141 approximately constant in the thickness direction, e.g., in the range of 1×10²¹ to 1×10²²/cm³. The nitrogen concentration of the oxynitride film 141 is higher than that of the oxidized film 143.

The oxygen concentration in the oxynitride film 141 increases as getting deeper and is lower than the oxygen concentration before the first heat treatment at all thickness. The concentration of Ga—O bonded oxygen at the interface 140 is 0.8 to 1.2 at %, which is lower than that before the first heat treatment. The concentration of Ga—O bonded oxygen at the interface 140 before the first heat treatment is 2 to 3 at %.

Next, an oxide film 142 is formed on the oxynitride film 141 (FIG. 4(c), S4 in FIG. 5). As the forming method of the oxide film 143, CVD, ALD, or sputtering is used. The thickness of the oxide film 143 is, for example, 40 to 100 nm.

Next, heat treatment is performed in an inert gas atmosphere (S5 in FIG. 5). This heat treatment is hereinafter referred to as second heat treatment. The inert gas is nitrogen. The temperature of the second heat treatment is lower than that of the first heat treatment. The temperature in the second heat treatment is, for example, 400 to 600° C. The time of the second heat treatment is, for example, 10 to 30 minutes. The second heat treatment can repair defects in the oxide film 142, facilitate recombination in the film, and improve insulation property.

In the forming method of the gate insulating film 14 described above, the concentration of Ga—O bonded oxygen at the interface 140 can be reduced while curtailing damage to the first semiconductor layer 11, the second semiconductor layer 12, and the third semiconductor layer 13. Thus, current leakage can be curtailed.

### 4. Results of Various Experiments

Next, the results of various experiments according to the embodiment will be explained.

### Experiment 1

A semiconductor device according to the embodiment (hereinafter referred to as Example 1) was prepared and the Id-Vd characteristics were investigated. In the gate insulating film 14, the thickness of oxide film 143 was set to 53 nm and the thickness of the oxide film 142 was set to 50 nm. The microwave output in nitrogen plasma treatment was set to 200 W. For comparison, a semiconductor device (hereafter referred to as Comparative Example 1) was prepared similarly to Example 1 except without performing the nitrogen plasma treatment and the first heat treatment as performed on Example 1, and the Id-Vd characteristics were similarly investigated.

FIG. 6 is a graph showing Id-Vd characteristics of the semiconductor device of Comparative Example 1. FIG. 6 shows that when a gate voltage Vg is −2 V or more, a drain current Id flows and current leakage occurs. This current leakage is considered to be caused by Ga—O bond being formed at the interface 140 between the second semiconductor layer 12 and the oxynitride film 141 on the side surface of trench 20.

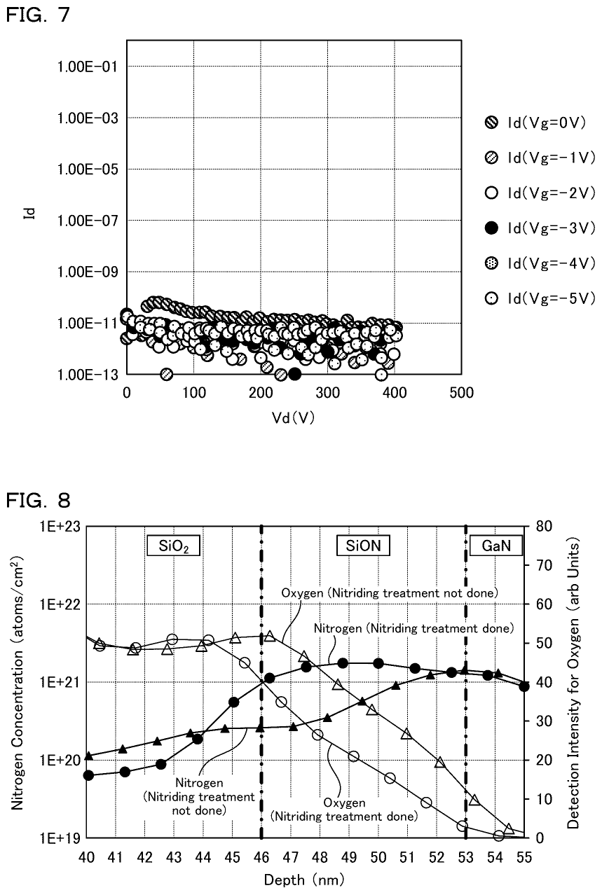

FIG. 7 is a graph showing Id-Vd characteristics of the semiconductor device of Example 1. IG. 7 shows that even when gate voltage Vg is set to 0 V, a drain current Id is 0.01 nA or less, which indicates that no current leakage occurs. This is considered to be because the nitrogen plasma treatment and the first heat treatment reduced the Ga—O bond at the interface 140 between the GaN and the oxynitride film 141 under the gate insulating film 14 (especially at the interface 140 between the second semiconductor layer 12 and the oxynitride film 141).

### Experiment 2

The gate insulating film 14 was formed on n-GaN, and the gate electrode 15 made of TiN was formed on the gate insulating film 14 to thereby prepare a sample (hereinafter referred to as Example 2). The gate insulating film 14 was made similar to the gate insulating film in Experiment 1. In addition, a sample (Comparative Example 2) was prepared similarly to Example 2 except without performing the nitrogen plasma treatment and the first heat treatment as performed in Example 2. For both Example 2 and Comparative Example 2, nitrogen concentration and oxygen concentration in the gate insulating film 14 were measured by SIMS.

FIG. 8 is a graph showing the relation between depth and nitrogen, and the relation between depth and oxygen concentration. The depth shown on the horizontal axis in FIG. 8 is a depth in the n-GaN direction with reference to the top surface of the gate insulating film 14. In both Example 2 and Comparative Example 2, the position at a depth of 46 nm is considered to be the interface between the oxide film 142 and the oxynitride film 141 of the gate insulating film 14. This is because the oxygen concentration is approximately constant at a depth of 46 nm or less. In both Example 2 and Comparative Example 2, the position at a depth of 53 nm is considered to be the interface 140 between the GaN layer and the oxynitride film 141. This is because the nitrogen concentration is constant here.

In the range of 45 to 53 nm depth, the oxygen concentration was lower in Example 2 than in Comparative Example 2. This suggests that the Ga—O bond at the interface 140 is reduced more in Example 2 than in Comparative Example.

In addition, in Example 2, at a depth of around 46 nm, the nitrogen concentration increased as the depth increased, the oxygen concentration decreased with the depth increased, and neither the nitrogen concentration nor the oxygen concentration was constant. In the case of SiN, the nitrogen concentration would be approximately constant and the oxygen concentration would be lower. Therefore, it can be inferred that there is no SiN between the oxide film 142 and the oxynitride film 141.

### Experiment 3

For Example 2 and Comparative Example 2, the 3d spectrum of Ga and the 1 s spectrum of O at the Ga—O bond in gate insulating film 14 were measured by XPS to measure the depth dependencies of gallium concentration and oxygen concentration.

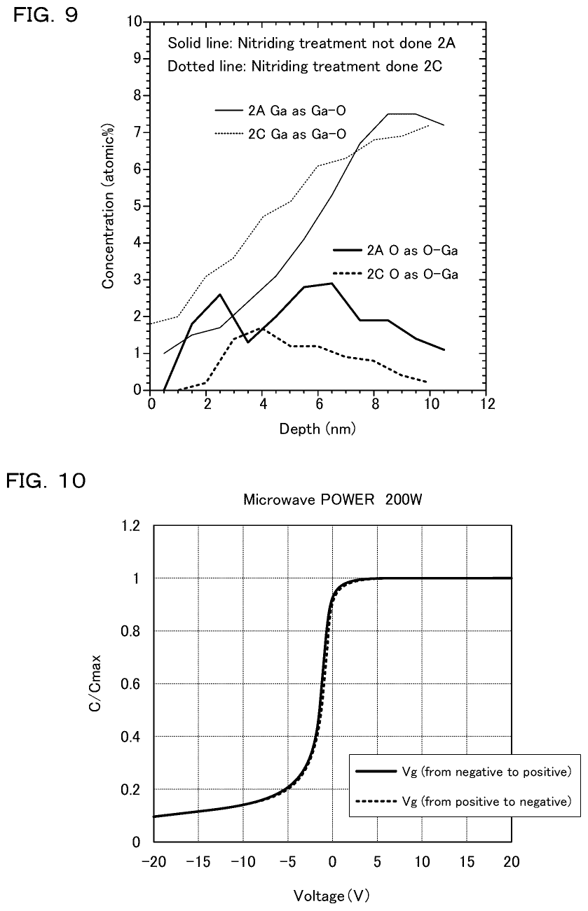

FIG. 9 is a graph showing the relation between the depth and the gallium concentration and the relation between the depth and the oxygen concentration. The depth shown on the horizontal axis in FIG. 9 is the depth in the p-GaN direction of a sample, which has an insulating film with a thickness of 7 nm on p-GaN, with reference to the insulating film surface. The concentration shows the concentrations of Ga—O bonded gallium and oxygen (at %). The 7 nm depth position is considered to be the interface 140 between the GaN layer and the oxynitride film 141.

As shown in FIG. 9, in Comparative Example 2 prepared without nitrogen plasma treatment, the oxygen concentration peaks at a depth of around 6 nm and is approximately 2.8 at %. It can also be seen that the gallium concentration increases as the depth increases and gets constant at a depth of around 8 nm. This suggests that Ga—O bond exists at a depth of around 6 nm. In Comparative Example 2, there is also an oxygen concentration peak at a depth of around 2.5 nm, however, this may be because oxygen enters by sputtering on the gate insulating film 14 when measured in the depth direction using XPS.

On the other hand, in Example 2 on which nitrogen plasma treatment was performed, there is no peak at a depth of around 6 nm as seen in Comparative Example 2, there is a peak at a depth of around 4 nm. The oxygen concentration at the peak is approximately 1.6 at %, and the oxygen concentration decreases gradually as the depth increases. The oxygen concentration is totally lower than in Comparative Example 2. Furthermore, it can be seen that the gallium concentration increases as the depth increases. Therefore, it is suggested that the Ga—O bond at the interface 140 is reduced in Example 2 compared to Comparative Example 2.

Regarding the nitrogen and oxygen concentrations in the interface 140 and the oxynitride film 141 in Example 2, FIG. 8 and FIG. 9 shows the following.

At the interface 140 between the GaN layer and the oxynitride film 141, the concentration of Ga—O bonded oxygen atoms is 0.8 to 1.2 at %. In addition, the nitrogen concentration in the interface 140 is 1×10²¹ to 1×10²²/ cm³.

The oxygen concentration in the oxynitride film 141 has a distribution in the direction of thickness and increases as getting closer to the oxide film 142. The nitrogen concentration in the oxynitride film 141 is approximately constant in the thick direction, ranging from 1×10²¹ to 1×10²²/ cm³.

### Experiment 4

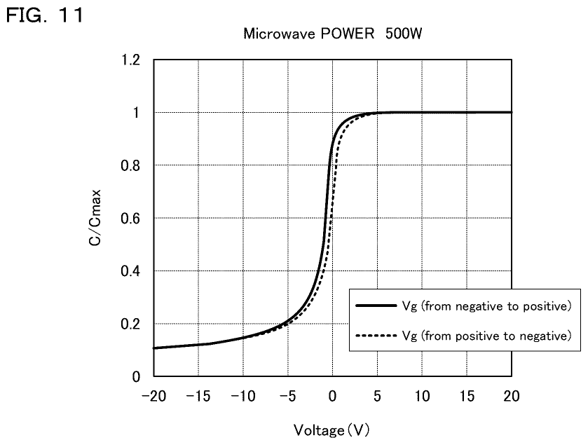

The gate insulating film 14 was formed on the n-GaN, and the gate electrode 15 made of TiN was formed on the gate insulating film 14 to prepare a sample. The microwave outputs in nitrogen plasma treatment were 200 W and 500 W. The C-V characteristics of the sample was measured. FIG. 10 is a graph showing the C-V characteristics in the case of setting the microwave output to 200 W. FIG. 11 is a graph showing the C-V characteristics in the case of setting the microwave output to 500 W.

As shown in FIG. 10, no hysteresis is viewed when microwave output was set to 200 W. In other words, there is no change in the C-V Curve between the case where the voltage was swept in the forward direction from negative to positive and the case of being swept in the reverse direction from positive to negative.

On the other hand, as shown in FIG. 11, hysteresis is viewed when microwave output was set to 500 W. In other words, there is seen a difference in the C-V Curve between the case where the voltage was swept in the forward direction and the case of being swept in the reverse direction.

The hysteresis in the C-V characteristics which is found in the case of setting the microwave output to 500 W suggests that there is a level (defect) at the interface between the GaN and the Insulating film. This may be because defects due to plasma damage is formed in GaN in the nitrogen plasma treatment. Because no hysteresis is viewed when the microwave output was set to 200 W, it is considered that the lowered plasma output reduced plasma damage to GaN, and thus the defects in GaN reduced.

### Modification of Embodiment

Although the semiconductor device of the embodiment is a MISFET with a trench gate structure, the present disclosure can be applied to any semiconductor device having a gate insulating film.

In addition, instead of or in addition to the gate insulating film 14, a protective film for a semiconductor device may have a structure similar to the gate insulating film 14. In this case also, current leakage at the interface between the semiconductor layer and the protective film can be curtailed while damage to the semiconductor is curtailed. In short, the present disclosure is applied not only to a gate insulating film and a protective film, but can be applied to any configuration in which an insulating film is provided on a semiconductor layer made of a group III nitride semiconductor.

Instead of SiO₂, any materials with an insulation property can be used for the oxide films 142 and 143. For example, Al₂O₃ may be used for the oxide films 142 and 143. In this case, the oxynitride film 141 is made of AlON. The oxide film 142 and the oxide film 143 may be made of different materials.

What is claimed is:

1. A method for manufacturing a semiconductor device, the method comprising:
a first oxide film forming step of forming a first oxide film with an insulation property on or above a semiconductor layer made of a group III nitride semiconductor;
a nitrogen plasma treatment step of irradiating the first oxide film with nitrogen plasma, thereby injecting nitrogen into the first oxide film;
a first heat treatment step of performing first heat treatment on the first oxide film to nitride the first oxide film, thereby forming an oxynitride film;
a second oxide film forming step of forming a second oxide film with an insulation property on or above the oxynitride film; and
a second heat treatment step of performing second heat treatment on the second oxide film, wherein
in the nitrogen plasma treatment step, a microwave output is set to 300 W or less.

2. The method for manufacturing a semiconductor device according to claim 1, wherein an interface between the semiconductor layer and the oxynitride film is nitrided by performing the first heat treatment to reduce a concentration of Ga—O bonded oxygen at the interface to a level lower than before the first heat treatment step.

3. The method for manufacturing a semiconductor device according to claim 2, wherein the concentration of Ga—O bonded oxygen is reduced to 0.8 to 1.2 at %.

4. A method for manufacturing a semiconductor device, the method comprising:
a first oxide film forming step of forming a first oxide film with an insulation property on or above a semiconductor layer made of a group III nitride semiconductor;
a nitrogen plasma treatment step of irradiating the first oxide film with nitrogen plasma, thereby injecting nitrogen into the first oxide film;
a first heat treatment step of performing first heat treatment on the first oxide film to nitride the first oxide film, thereby forming an oxynitride film;
a second oxide film forming step of forming a second oxide film with an insulation property on or above the oxynitride film; and
a second heat treatment step of performing second heat treatment on the second oxide film, wherein
an interface between the semiconductor layer and the oxynitride film is nitrided by performing the first heat treatment to reduce a concentration of Ga—O bonded oxygen at the interface to 0.8 to 1.2 at %.

5. The method for manufacturing a semiconductor device according to claim 1, wherein in the nitrogen plasma treatment step, a nitrogen concentration of the first oxide film is made to be 1×10²⁰ to 1×10²²/ cm³.

6. The method for manufacturing a semiconductor device according to claim 1, wherein in the nitrogen plasma treatment step, a nitrogen concentration in a region of the first oxide film near an interface between the semiconductor layer and the first oxide film is made to be 1×10²¹ to 1×10²²/ cm³.

7. The method for manufacturing a semiconductor device according to claim 1, wherein in the first oxide film forming step, the first oxide film is formed to have a thickness of 1 nm or more and 9 nm or less.

8. The method for manufacturing a semiconductor device according to claim 4, wherein in the nitrogen plasma treatment step, a nitrogen concentration of the first oxide film is made to be 1×10²⁰ to 1×10²²/ cm³.

9. The method for manufacturing a semiconductor device according to claim 4, wherein in the nitrogen plasma treatment step, a nitrogen concentration in a region of the first oxide film near an interface between the semiconductor layer and the first oxide film is made to be 1×10²¹ to 1×10²²/ cm³.

10. The method for manufacturing a semiconductor device according to claim 4, wherein in the first oxide film forming step, the first oxide film is formed to have a thickness of 1 nm or more and 9 nm or less.

11. A semiconductor device comprising:
a semiconductor layer made of a group III nitride semiconductor;
a gate insulating film formed on the semiconductor layer; and
a gate electrode formed on the gate insulating film, wherein
the gate insulating film including:
an SiON film formed on the semiconductor layer, and 10
an SiO₂ film formed on the SiON film in contact therewith, and
a concentration of Ga—O bonded oxygen at an interface between the semiconductor layer and the SiON film is 0.8 to 1.2 at %.
